(19) United States
(12) Patent Application Publication
(10) Pub. No.: US 2023/0303853 A1
(43) Pub. Date: Sep. 28, 2023

(54) CONTINUOUS THREE-DIMENSIONAL PRINTING OF ARCHITECTED PIEZOELECTRIC SENSORS

(71) Applicants: Siying Liu, Gilbert, AZ (US); Wenbo Wang, Gilbert, AZ (US); Xiangfan Chen, Chandler, AZ (US)

(72) Inventors: Siying Liu, Gilbert, AZ (US); Wenbo Wang, Gilbert, AZ (US); Xiangfan Chen, Chandler, AZ (US)

(21) Appl. No.: 18/190,346

(22) Filed: Mar. 27, 2023

Related U.S. Application Data
(60) Provisional application No. 63/324,453, filed on Mar. 28, 2022.

(51) Int. Cl. C09D 4/06; B29C 64/124; B29C 64/393; B33Y 10/00; B33Y 50/02; B33Y 70/10; C09C 3/12; C09C 1/36; C09C 1/40; C09D 171/02; C09D 7/62; C09D 7/63; C09D 5/24; H10N 30/857; H10N 30/853; H10N 30/098

(52) U.S. Cl. CPC C09D 4/06; B29C 64/124; B29C 64/393; B33Y 10/00; B33Y 50/02; B33Y 70/10; C09C 3/12; C09C 1/36; C09C 1/40; C09D 171/02; C09D 7/62; C09D 7/63; C09D 5/24; H10N 30/857; H10N 30/8536; H10N 30/8554; H10N 30/098; B29K 2033/12

(57) ABSTRACT

A photocurable resin may comprise piezonanoparticles. The piezonanoparticles may comprise functionalized barium titanate (f-BTO), functionalized lead zirconate titanate (f-PZT), or functionalized aluminum nitride (f-AlN). The photocurable resin may further comprise a photo-initiator, a photo-absorber, or PEGDA 700.

### CROSS REFERENCE TO RELATED APPLICATIONS

This application claims priority to, and the benefit of, U.S. Provisional Patent Application Ser. No. 63/324,453 entitled “CONTINUOUS THREE-DIMENSIONAL PRINTING OF ARCHITECTED PIEZOELECTRIC SENSORS” filed on Mar. 28, 2022. The content of the foregoing application is hereby incorporated by reference (except for any subject matter disclaimers or disavowals, and except to the extent of any conflict with the disclosure of the present application, in which case the disclosure of the present application shall control).

### TECHNICAL FIELD

The present disclosure relates to the manufacture of piezoelectric materials, and in particular to piezoelectric materials that can be 3D-printed.

### BACKGROUND

Piezoelectric materials have enabled diverse applications such as energy harvesting and self-powered sensing. Materials include inorganic ceramics and organic polymers and co-polymers. Nonetheless, neither the piezoelectric ceramics nor the piezoelectric polymers are able to simultaneously meet the demands from applications in flexible, wearable, or implantable electronics in terms of piezoelectric performance, mechanical flexibility, and ease of processability. As such, a piezoelectric material with high piezoelectric performance, mechanical flexibility, and ease of processability is desirable. For example, a 3D-printable piezoelectric material.

### SUMMARY

A photocurable resin is disclosed herein. The photocurable resin may include piezonanoparticles (PiezoNPs).

In various embodiments, the PiezoNPs may include functionalized barium titanate (f-BTO), functionalized lead zirconate titanate (f-PZT), or functionalized aluminum nitride (f-AlN). The f-BTO may have a weight ratio of up to 30 wt %. In particular, the f-BTO may have a weight ratio of 0 wt %, 5 wt %, 10 wt %, 15 wt %, 20 wt %, 25 wt %, or 30 wt %. The f-PZT may have a weight ratio of up to 20 wt %. In particular, the f-PZT may have a weight ratio of 10 wt % or 20 wt %. The f-AlN may have a weight ratio of up to 15 wt %.

In various embodiments, the photocurable resin may further include PEGDA 700. In various embodiments, the photocurable resin may further include a photo-initiator and a photo-absorber. The photo-initiator may include phenylbis(2,4,6-trimethylbenozyl)phosphine oxide (Irgacure 819). The weight ratio of the photo-initiator may be 2 wt %. The photo-absorber may include 2-(2H-benzotriazol-2-yl)-6-dodecyl-4-methylphenol (Tinuvin 171). The weight ratio of the photo-absorber may be 0.2 wt %.

A method of manufacturing piezoelectrical materials is disclosed herein. The method may include: providing a photocurable resin, comprising piezonanoparticles (PiezoNPs), in a resin bath; slicing a 3D model of the piezoelectric material into a series of 2D images; projecting a first 2D image onto an oxygen-permeable thin film embedded underneath the resin bath; monitoring a focusing status of the projection of the first 2D image; when the projection of the first 2D image is complete, projecting a second 2D image onto the oxygen-permeable thin film; and when the projection of the second 2D image is complete, projecting the remainder of the 2D images, one at a time, onto the oxygen-permeable thin film.

In various embodiments, the method may further include characterizing the resulting piezoelectric material. The photocurable resin may include functionalized barium titanate (f-BTO), functionalized lead zirconate titanate (f-PZT), or functionalized aluminum nitride (f-AlN). The photocurable resin may include f-BTO with a concentration of f-BTO of up to 30 wt %. The photocurable resin may include f-PZT with a concentration of f-PZT of up to 20 wt %. The photocurable resin may include f-AlN with a concentration of f-AlN of up to 15 wt %. The thickness of each 2D image may be about 5 micrometers. The 2D images may be projected using a light source including a wavelength of about 385 nanometers. The oxygen-permeable film may include Teflon AF2400.

The foregoing features and elements may be combined in various combinations without exclusivity, unless expressly indicated otherwise. These features and elements as well as the operation thereof will become more apparent in light of the following description and the accompanying drawings. It should be understood, however, the following description and drawings are intended to be exemplary in nature and non-limiting. The contents of this section are intended as a simplified introduction to the disclosure and are not intended to limit the scope of any claim.

### BRIEF DESCRIPTION OF THE DRAWINGS

With reference to the following description and accompanying drawings:

FIGS. 1A, 1B, and 1C illustrate a schematic of continuous three-dimensional printing of architected piezoelectric sensors, in accordance with an exemplary embodiment;

FIG. 2 illustrates the characterization of optimal printing speed of f-BTO resins, in accordance with an exemplary embodiment;

FIG. 3 illustrates a comparison between an exemplary embodiment and other reported works in terms of printing speed and piezoelectric performance;

FIG. 4 illustrates 3D-printed sophisticated, multi-scale f-BTO structures, in accordance with an exemplary embodiment;

FIGS. 5A through 5K illustrate piezoelectric sensing applications with the 3D-printed f-BTO composites, in accordance with various exemplary embodiments; and

FIG. 6 illustrates a schematic of the unit cells used for piezoelectric characterizations and sensing applications, in accordance with an exemplary embodiment.

### DETAILED DESCRIPTION

The following description is of various exemplary embodiments only, and is not intended to limit the scope, applicability or configuration of the present disclosure in any way. Rather, the following description is intended to provide a convenient illustration for implementing various embodiments including the best mode. As will become apparent, various changes may be made in the function and arrangement of the elements described in these embodiments without departing from principles of the present disclosure.

For the sake of brevity, conventional techniques and components may not be described in detail herein. Furthermore, the connecting lines shown in various figures contained herein are intended to represent exemplary functional relationships and/or physical couplings between various elements. It should be noted that many alternative or additional functional relationships or physical connections may be present in exemplary systems and/or components thereof.

In various exemplary embodiments, a photocurable resin with piezoelectric properties may be desirable for flexible, wearable, or implantable electronics. Exemplary embodiments are intended to be, or function as, photocurable resins with piezoelectric properties.

Exemplary embodiments are intended to be used to manufacture three-dimensional piezoelectric material structures through 3D-printing. The photocurable resin utilizes piezonanoparticles (PiezoNPs) to provide piezoelectric character to a photocurable resin.

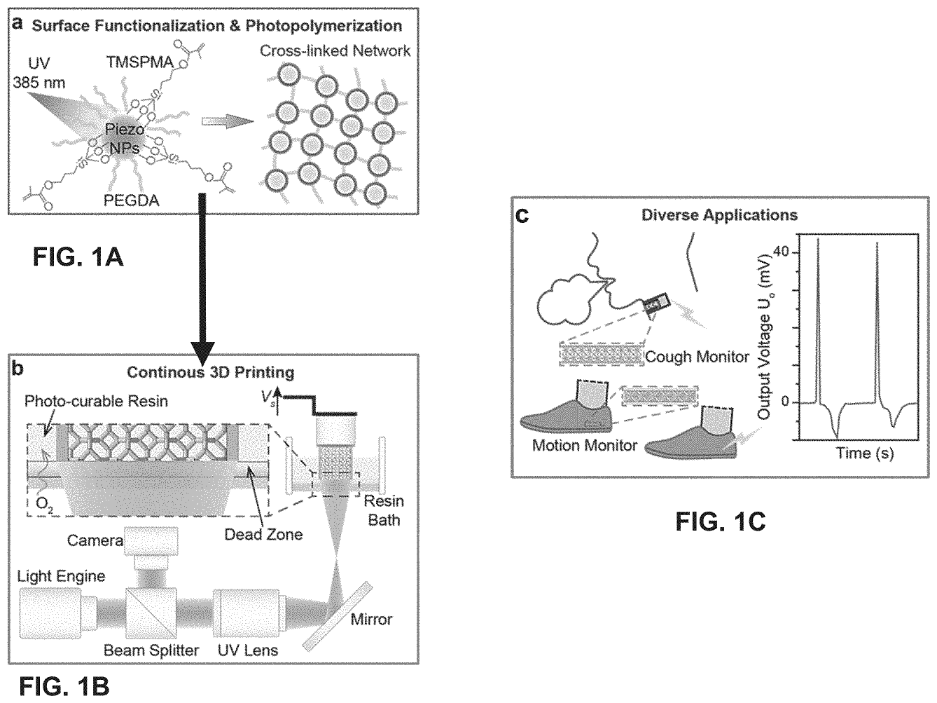

Referring now to FIG. 1A, a PiezoNP is illustrated. The PiezoNP is functionalized into a functionalized PiezoNP (f-PiezoNP) through reaction with a functionalizing group. In various embodiments, the functionalizing group includes 3-(trimethoxysilyl)propylmethacrylate (TMSPMA). In various embodiments, the PiezoNP used is BTO, PZT, or AlN. Functionalization of the PiezoNP avoids the agglomeration and precipitation of PiezoNPs from the photocurable resin and ensures the homogenous properties of 3D-printed parts. The functionalizing group enables steric hinderance that stabilizes the colloids as well as co-polymerization of the f-PiezoNPs during printing. Unfunctionalized BTO nanoparticles rapidly agglomerate and sediment onto the transparent window, causing devastating scattering of the input UV light and inhibiting the continuous flow-in of resins, all of which will eventually lead to disrupted printings.

In various embodiments, f-PiezoNPs are dispersed into PEGDA 700. In various embodiments, the resulting weight ratio of f-BTO is up to 30 wt %. In various embodiments, the weight ratio of f-BTO is 0 wt %, 5 wt %, 10 wt %, 15 wt %, 20 wt %, 25 wt %, or 30 wt %. In various embodiments, the resulting weight ratio of f-PZT is up to 20 wt %. In various embodiments, the weight ratio of f-PZT is 10 wt % or 20 wt %. In various embodiments, the weight ratio of f-AN is up to 15 wt %.

In various embodiments, the photocurable resin further comprises a photo-initiator and a photo-absorber. In various embodiments, the photo-initiator comprises phenylbis(2,4,6-trimethylbenzoyl)phosphine oxide (Irgacure 819). In various embodiments, the weight ratio of the photo-initiator is 2 wt %. In various embodiments, the photo-absorber comprises 2-(2H-benzotriazol-2-yl)-6-dodecyl-4-methylphenol (Tinuvin 171). In various embodiments, the weight ratio of the photo-initiator is 0.2 wt %.

Referring now to FIG. 1B, a customized micro-continuous liquid interface production (μCLIP) method of manufacturing piezoelectric materials is illustrated. In various embodiments, the method comprises providing a photocurable resin, comprising PiezoNPs, in a resin bath; slicing a 3D model of the piezoelectric material into a series of 2D images; projecting a first 2D image onto an oxygen-permeable thin film embedded underneath the resin bath; monitoring a focusing status of the projected image; when the projection of the first 2D image is complete, projecting a second 2D image onto the oxygen-permeable thin film; and when the projection of the second 2D image is complete, projecting the remainder of the 2D images, one at a time, onto the oxygen-permeable thin film.

In various embodiments, computer-aided design (CAD) software is utilized to design and generate 3D models of the to-be-printed piezoelectrical materials. The CAD models are then sliced layer-by-layer into a series of 2D images. In various embodiments, the 3D models are sliced by a customized slicing program with a pre-defined layer thickness of 5 micrometers.

In various embodiments, the 2D image is projected by a light engine equipped with a 385-nanometer light source and a digital micromirror device. In various embodiments, the light engine has a resolution of 1280×800. In various embodiments, a UV lens is used to project the 2D image.

In various embodiments, the oxygen-permeable thin film comprises Teflon AF2400. In various embodiments, the oxygen-permeable thin film has a nominal thickness of 40 micrometers. In various embodiments, the oxygen-permeable thin film is embedded underneath a resin bath. In various embodiments, the resin bath is customized. In various embodiments, the resin bath yields a lateral resolution of 6.9×.6.9 μm² pixel⁻¹ and a maximum lateral printing area of 8.83×5.52 mm². In various embodiments a light intensity of 7.6 mW cm⁻² is used.

In various embodiments, a CCD camera is used to monitor the focusing status of projected images. In various embodiments a Z-axis motorized stage is used to control the printing platform with varying printing speeds based on pre-defined printing parameters. In various embodiments a desktop computer is used to control the printing procedure.

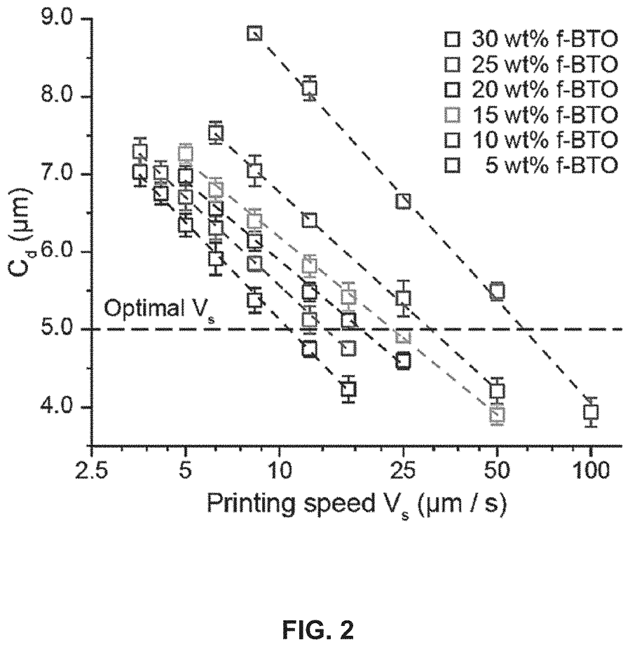

Referring now to FIG. 2, in various embodiments a speed working curve is used to experimentally parameterize the optimal printing speeds. The speed working curve model can be expressed as

$${C}_{d} = {D}_{p} \times ln ( \frac{{V}_{c}}{{V}_{s}} )$$

where C_{d} is the curing depth, Dₚ is the penetration depth of the input UV light, V_{c} is the threshold moving speed of the printing platform, and Vₛ is the actual moving speed of the printing platform. The measured C_{d} versus logarithmic Vₛ for resins with different solid loadings were plotted and fitted according to the underlying curing model, which can guide the determination of the optimal printing speed, Vₛ.

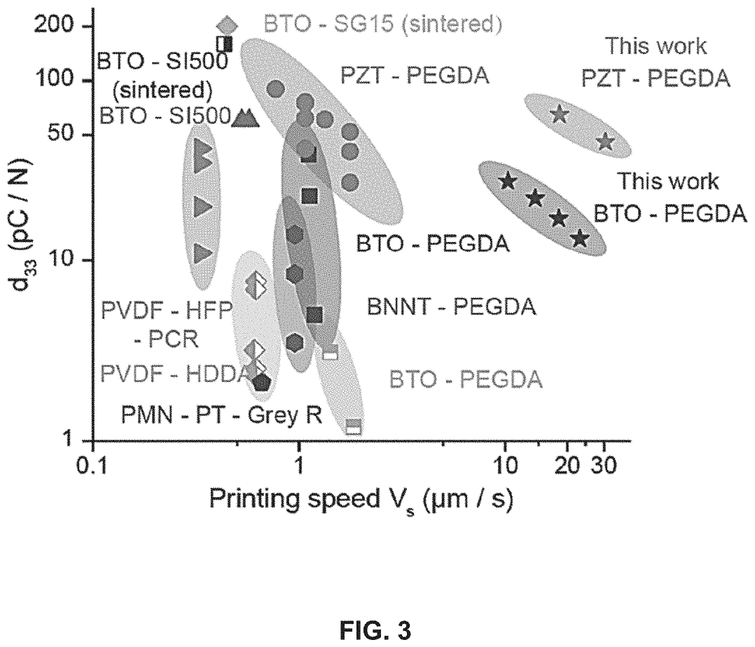

Referring now to FIG. 3, in various embodiments, the procedure is capable of fabricating 3D structures with piezoelectric performance comparable to state-of-the-art projection micro-stereolithography (PμSL)-based works at speeds that are at least one order of magnitude faster.

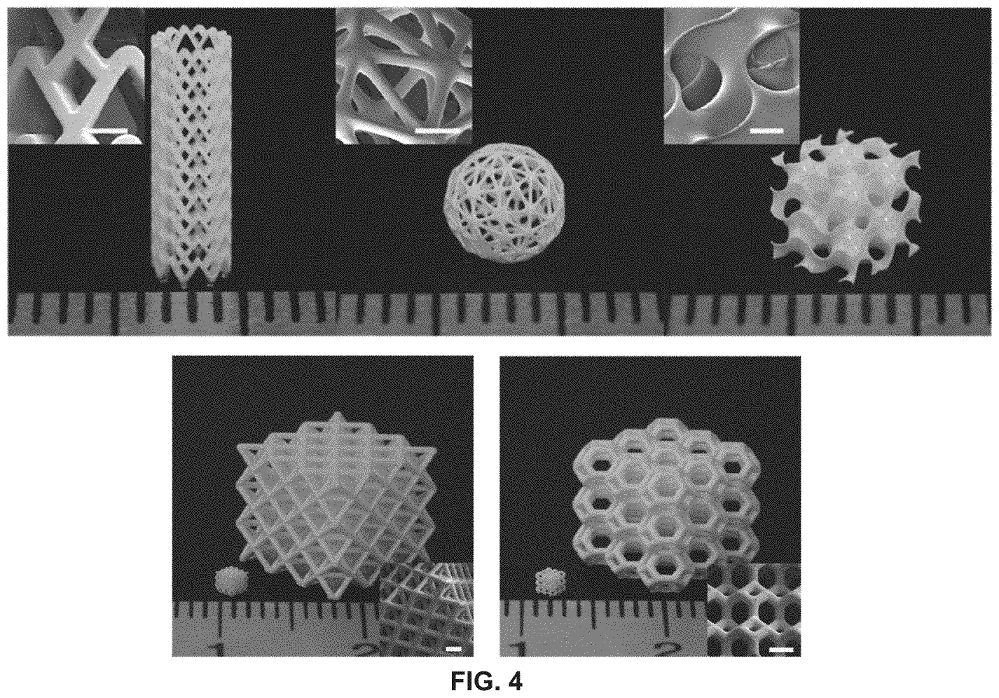

Referring now to FIG. 4, in various embodiments, using the parameters determined above, sophisticated 3D structures, including a vascular stent, a hollow lattice ball, and a gyroid structure may be printed using the f-BTO resin. Moreover, in various embodiments, it is possible to yield 3D structures (e.g., octet-truss and Kelvin lattices) ranging from micrometer to centimeter-scale.

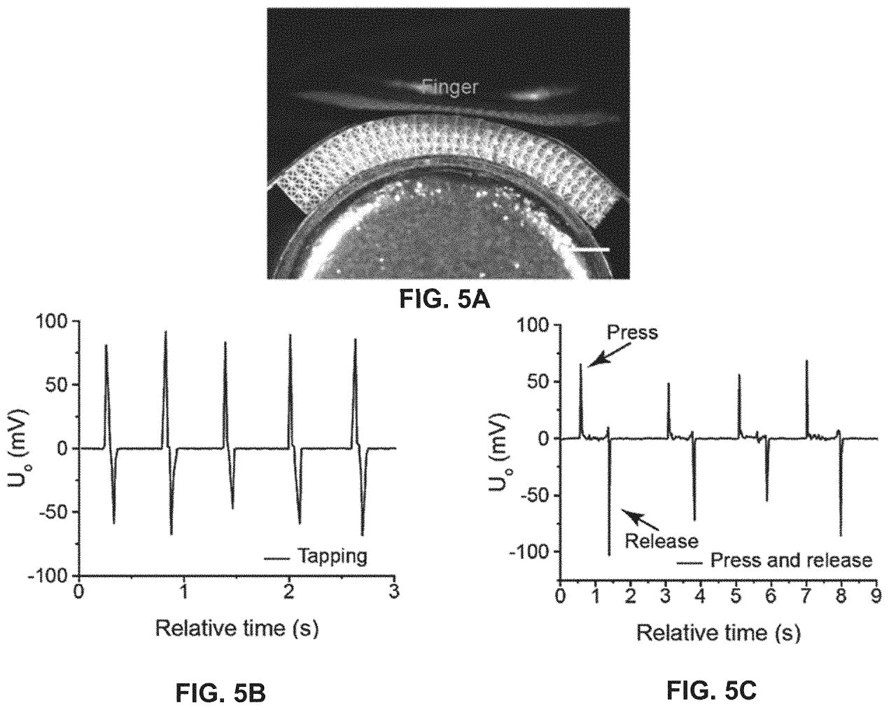

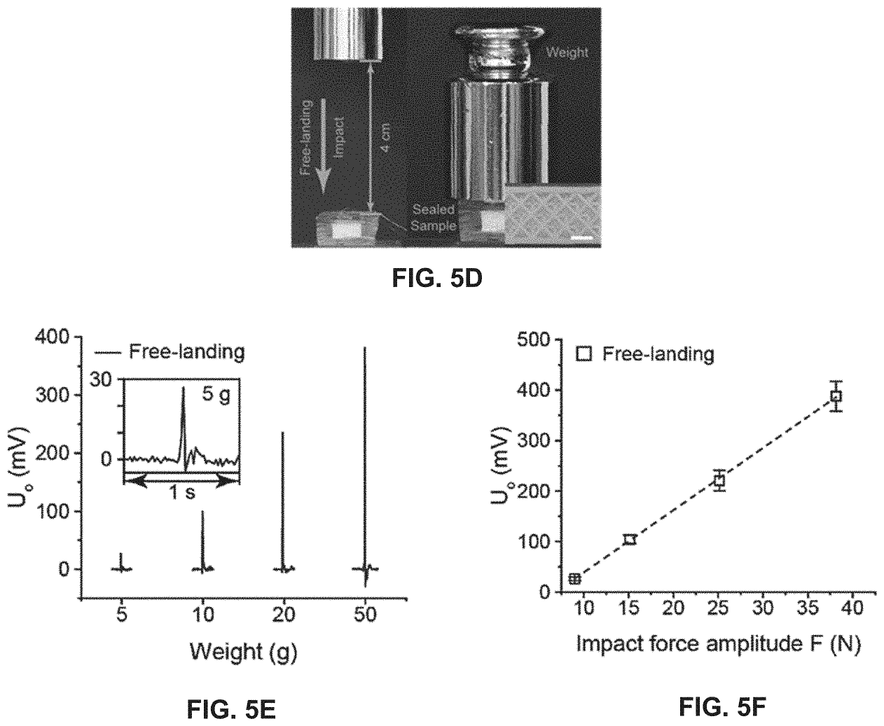

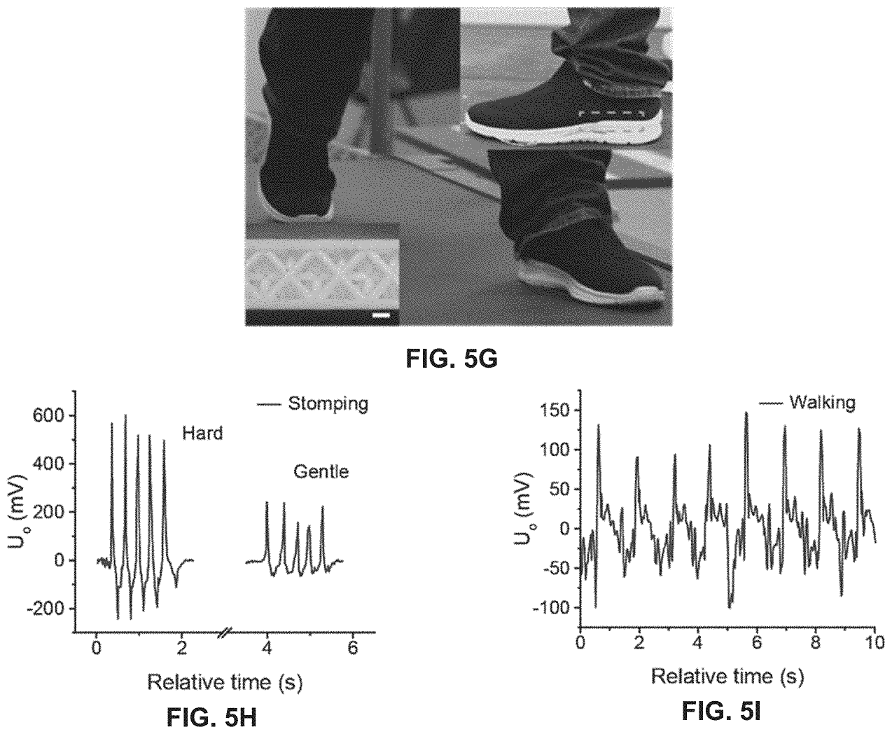

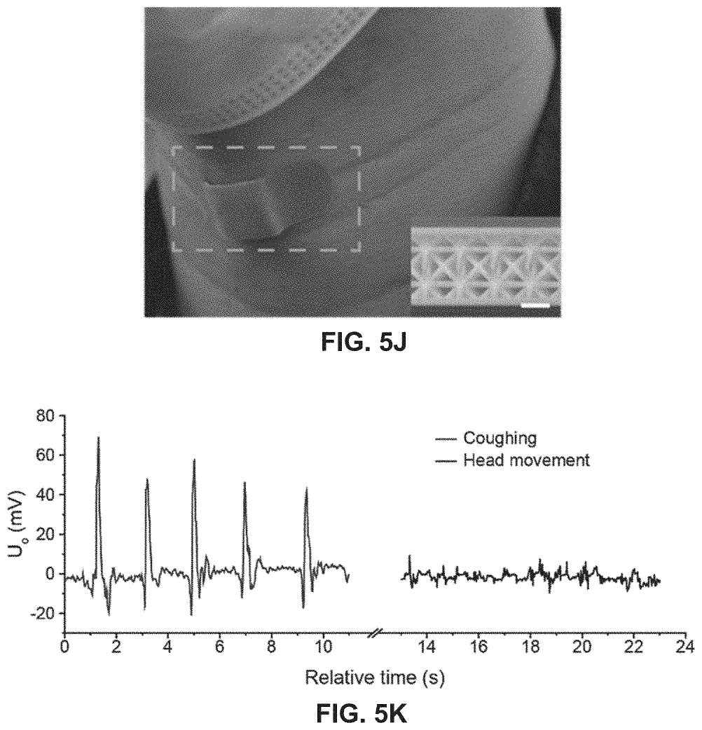

Referring now to FIG. 5, in various embodiments the resulting material is suitable for use in various sensing applications. Referring now to FIG. 5A, in various embodiments the resulting material can be easily folded to a great extent and conformally mounted onto curved surfaces due to superior mechanical compliance. Referring now to FIGS. 5B and 5C, in various embodiments the resulting material may generate a voltage signal as the result of tapping or of a press and release. Referring now to FIGS. 5D, 5E, and 5F, in various embodiments the resulting material may retain their reliable functionalities under scenarios in which an integrated package is desirable. In various embodiments, the resulting material may generate a voltage signal as the result of impact from a free-falling mass. In various embodiments, sealings do not deteriorate the effectiveness of the 3D printed structures as quantifiable, source-free sensors that can deliver instantaneous responses for multi-purpose applications once they are calibrated. Referring now to FIGS. 5G, 5H, and 5I, in various embodiments the resulting material may generate a voltage signal as the result of an individual walking or stomping on the material. In various embodiments, the resulting material may be directly mounted into a shoe or other footwear. Referring now to FIGS. 5J and 5K, in various embodiments the resulting material may generate a voltage signal as the result of an individual coughing or moving their head while mounted as a respiratory monitoring device.

### WORKING EXAMPLES

### Example 1. Surface Functionalization of BTO, PZT, and AlN Nanoparticles

About 1.5 g of BTO nanoparticles were dispersed into 200 mL of ethanol, to which 5 mL of TMSPMA was added using a syringe needle. The mixture was sonicated for 1 h, then 15 mL of diluted acetic acid solution (10 vol % in water) was added to the mixture prior to functionalization. The mixture was then vigorously stirred at room temperature for 24 h. After that the functionalized BTO nanoparticles were recollected and cleaned with pure ethanol via centrifugation for at least three cycles. The functionalized BTO nanoparticles were then dried in vacuum at 80° C. overnight and used for preparing the resins. About 1 g of PZT or about 0.75 g of AlN per batch were functionalized via the same procedure as stated above.

### Example 2. Preparation of the Functionalized, Photo-Polymerizable Resins

f-BTO nanoparticles were dispersed into PEGDA 700 to yield f-BTO weight ratios of 0, 5, 10, 15, 20, 25, and 30 wt %, respectively. Irgacure 819 (photo-initiator) and Tinuvin 171 (photo-absorber) were added to the resins with fixed weight ratios of 2 wt % and 0.2 wt %, respectively. All resins were thoroughly mixed in an ultrasonic bath for about 8 h prior to use. 10 and 20 wt % f-PZT resins and 15 wt % f-AN resins were prepared similarly with fixed 2 wt % Irgacure 819 and 0.2 wt % Tinuvin 171.

### Example 3. Customized μCLIP 3D Printing Setup

Computer-aided design (CAD) software was utilized to design and generate 3D models of the to-be-printed structures. These CAD models were then sliced layer-by-layer into a series of 2D images by a customized slicing program with a pre-defined layer thickness of 5 μm. A light engine (Pro4500, Wintech Digital) equipped with a 385 nm UV light source and a digital micromirror device (DMD, Texas Instruments) with a resolution of 1280×800 was used as the optical input to generate the sliced 2D images. A UV lens (UV8040BK2, Universe Optics) was used to project the generated images onto an oxygen-permeable thin film (Teflon AF2400, 40 μm nominal thickness, Biogeneral) embedded underneath a customized resin bath and yield a lateral resolution of 6.9×6.9 μm² pixel⁻¹ and a maximum lateral printing area of 8.83×5.52 mm². All the printings were conducted at a fixed light intensity of 7.6 mW cm². A CCD camera (MU2003-BI, AmScope) was used to monitor the focusing status of projected images. A Z-axis motorized stage (X-LSM200A-KX13A, Zaber Technology Inc.) was used to control the printing platform with varying printing speeds based on pre-defined printing parameters. A desktop computer was used to control the entire printing procedure.

### Example 4. Applications of Printed Piezoelectric Sensors

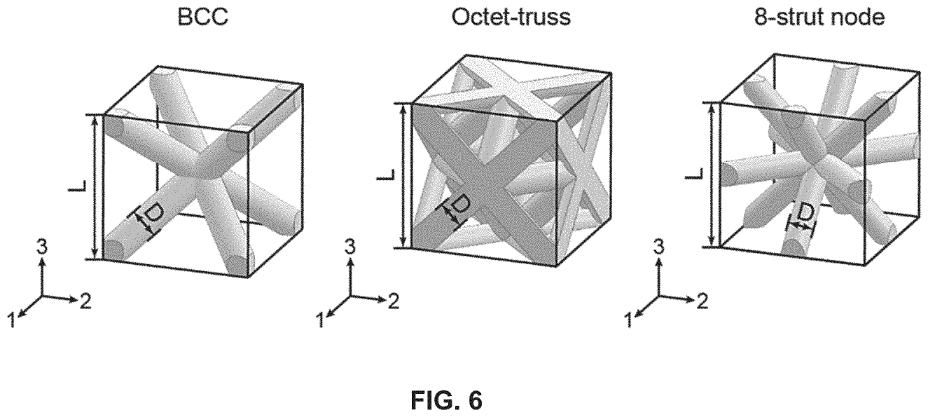

To further demonstrate the sensing capabilities, multiple 3D structures were printed using 30 wt % f-BTO resin and tested under a variety of scenarios. Schematics of the unit cells were depicted in FIG. 6.

Referring now to FIG. 6, the various geometric parameters associated with each printed structure is summarized in Table 1, below:

| Scenario of | | Unit cell length L | Beam diameter D |
|---|---|---|---|
| Characterization | Unit cell | (μm) | (μm) |
| Characterizations | BCC | 1500 | 275, 300, 325, |
| on lattice | | | 350, 375, 400 |
| structures | | | |
| Tapping/Press- | Octet-truss | 500 | 50 |
| and-release | | | |
| Free-landing | Octet-truss | 1500 | 280 |
| Stomping/ | Octet-truss | 1500 | 280 |
| Walking | | | |
| Respiratory | 8-strut node | 600 | 100 |
| monitoring | | | |

While the principles of this disclosure have been shown in various embodiments, many modifications of structure, arrangements, proportions, the elements, materials and components, used in practice, which are particularly adapted for a specific environment and operating requirements may be used without departing from the principles and scope of this disclosure. These and other changes or modifications are intended to be included within the scope of the present disclosure.

The present disclosure has been described with reference to various embodiments. However, one of ordinary skill in the art appreciates that various modifications and changes can be made without departing from the scope of the present disclosure. Accordingly, the specification is to be regarded in an illustrative rather than a restrictive sense, and all such modifications are intended to be included within the scope of the present disclosure. Likewise, benefits, other advantages, and solutions to problems have been described above with regard to various embodiments. However, benefits, advantages, solutions to problems, and any element(s) that may cause any benefit, advantage, or solution to occur or become more pronounced are not to be construed as a critical, required, or essential feature or element.

As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. Also, as used herein, the terms “coupled,” “coupling,” or any other variation thereof, are intended to cover a physical connection, an electrical connection, a magnetic connection, an optical connection, a communicative connection, a functional connection, and/or any other connection. When language similar to “at least one of A, B, or C” or “at least one of A, B, and C” is used in the specification or claims, the phrase is intended to mean any of the following: (1) at least one of A; (2) at least one of B; (3) at least one of C; (4) at least one of A and at least one of B; (5) at least one of B and at least one of C; (6) at least one of A and at least one of C; or (7) at least one of A, at least one of B, and at least one of C.

What is claimed is:

1. A photocurable resin, comprising piezonanoparticles (PiezoNPs).

2. The photocurable resin of claim 1, wherein the PiezoNPs comprise functionalized barium titanate (f-BTO), functionalized lead zirconate titanate (f-PZT), or functionalized aluminum nitride (f-AlN).

3. The photocurable resin of claim 2, wherein the f-BTO, f-PZT, or f-AlN comprises 3-(trimethoxysilyl)propyl methacrylate (TMSPMA).

4. The photocurable resin of claim 2, wherein the PiezoNPs comprise f-BTO with a weight ratio of f-BTO of up to 30 wt %.

5. The photocurable resin of claim 4, wherein the weight ratio of f-BTO is 0 wt %, 5 wt %, 10 wt %, 15 wt %, 20 wt %, 25 wt %, or 30 wt %.

6. The photocurable resin of claim 2, wherein the PiezoNPs comprise f-PZT with a weight ratio of f-PZT of up to 20 wt %.

7. The photocurable resin of claim 6, wherein the weight ratio of f-PZT is 10 wt % or 20 wt %.

8. The photocurable resin of claim 2, wherein the PiezoNPs comprise f-AlN with a weight ratio of f-AlN of up to 15 wt %.

9. The photocurable resin of claim 1, wherein the photocurable resin further comprises PEGDA 700.

10. The photocurable resin of claim 1, wherein the photocurable resin further comprises a photo-initiator and a photo-absorber.

11. The photocurable resin of claim 10, wherein the photo-initiator comprises phenylbis(2,4,6-trimethylbenzoyl)phosphine oxide (Irgacure 819).

12. The photocurable resin of claim 10, wherein a weight ratio of the photo-initiator is 2 wt %.

13. The photocurable resin of claim 10, wherein the photo-absorber comprises 2-(2H-benzotriazol-2-yl)-6-dodecyl-4-methylphenol (Tinuvin 171).

14. The photocurable resin of claim 10, wherein a weight ratio of the photo-absorber is 0.2 wt %.

15. A method of manufacturing piezoelectric materials, comprising:
providing a photocurable resin, comprising PiezoNPs, in a resin bath;
slicing a 3D model of a piezoelectric material into a series of 2D images;
projecting a first 2D image onto an oxygen-permeable thin film embedded underneath the resin bath;
monitoring a focusing status of the projection of the first 2D image;
when the projection of the first 2D image is complete, projecting a second 2D image onto the oxygen-permeable thin film; and
when the projection of the second 2D image is complete, projecting the remainder of the 2D images, one at a time, onto the oxygen-permeable thin film.

16. The method of claim 15, wherein the method further comprises characterizing a resulting piezoelectric material.

17. The method of claim 15, wherein the PiezoNPs comprise f-BTO with a weight ratio of up to about 30 wt %, f-PZT with a weight ratio of up to about 20 wt %, and f-AlN with a weight ratio of up to about 15 wt %.

18. The method of claim 15, wherein a thickness of each 2D image is about 5 micrometers.

19. The method of claim 15, wherein 2D images are projected using a light source comprising a wavelength of about 385 nanometers.

20. The method of claim 15, wherein the oxygen-permeable thin film comprises Teflon AF2400.
